(19) United States
(12) Patent Application Publication
(10) Pub. No.: US 2010/0026330 A1
(43) Pub. Date: Feb. 4, 2010

(54) TESTBOARD WITH ZIF CONNECTORS, METHOD OF ASSEMBLING, INTEGRATED CIRCUIT TEST SYSTEM AND TEST METHOD INTRODUCED BY THE SAME

(76) Inventor: Yuan-Chi LIN, Zhunan Township (TW)

Correspondence Address: SINORICA, LLC, 2275 Research Blvd., Suite 500, ROCKVILLE, MD, 20850, US

(21) Appl. No.: 12/577,195

(22) Filed: Oct. 11, 2009

Related U.S. Application Data
(63) Continuation-in-part of application No. 11/889,397, filed on Aug. 13, 2007, now abandoned.

(51) Int. Cl. G01R 31/02

(52) U.S. Cl. 324/755

(57) ABSTRACT

A testboard with ZIF connectors is disclosed. The testboard comprises a test substrate, a plurality of ZIF connectors and a plurality of detachably adjustable fastening means. Each ZIF connector has a plurality of second through-holes, and pairs of electric terminals are deposed on the bottom of each ZIF connector where each pair of electric terminals has a radial shape for contacting the test substrate. Each fastening means is disposed through the first through-holes and the second through-holes through the middle of each ZIF connector for adjusting the ZIF connectors on the test substrate in better contact and for replacing each ZIF connector on the test substrate with a replacement ZIF connector where the second through-holes are arranged to one another in a spaced interval along a longitudinal direction, and each ZIF connector has a ratio of its longitudinal length to its spaced interval ranging from 3:1 to 5:1.

### CROSS-REFERENCE TO RELATED APPLICATIONS

This application is a Continuation in-part of and claims a priority to the U.S. application Ser. No. 11/889,397 entitled “Testboard with ZIF connectors, method of assembling, integrated circuit test system and test method introduced by the same” filed on Aug. 13, 2007. Also, the disclosure of the U.S. application Ser. No. 11/889,397 is incorporated herein.

### FIELD OF THE INVENTION

The present invention relates to a testboard and a test system having the testboard, and more particularly, to a testboard having a particular dimensional ratios, and a test system having the testboard of the particular dimensional ratios.

### BACKGROUND OF THE INVENTION

When general integrated circuit (IC) devices are performed to do final tests, electrical contacts or pins of the IC devices need to be pressed and contacted with pogo pins of sockets so as to transmit test signals through the pogo pins to a tester to verify the IC devices.

Refer to FIG. 1A. A schematic view of an IC device test system is illustrated. A control system 10 emits a test signal and passes it to a tester 12 as known by those skilled in the art. A motherboard 15 and ZIF (Zero Insertion Force) female plug connectors 17 are equipped on the tester 12. The ZIF female plug connectors 17 are connected with ZIF connectors 18 so as to transmit the test signal to the testboard 19. U.S. Pat. No. 6,184,698, U.S. Pat. No. 6,398,570, U.S. Pat. No. 6,478,596 as well as Taiwan Patent No. TW475984 have disclosed a method for connecting the ZIF female plug connectors 17 with the ZIF connectors 18. A testboard 19 is provided with probe pins 20 on its bottom for electrically connecting the ZIF connectors 18. A test system loads the IC device under test 21 onto a socket 22 so that the IC device 21 can be contacted with the probe pins 20 on the bottom of the testboard 19 via the movement of the socket 22 to perform the test as well as to send the test signal back to the control system 10.

Refer to FIG. 1B. A conventional connection mode of the ZIF connector 18 and the testboard 19 is shown. A rivet 201 directly passes through the ZIF connector 18 and the testboard 19, thus the ZIF connector 18 is riveted on the upper surface of the testboard 19. A plurality of golden fingers 202 are disposed on each of two sides of the ZIF connectors 18 so as to transmit test signals to the ZIF female plug connector 17. In addition, the golden fingers 202 are extended under the ZIF connector 18 and extended outwardly to form a radial shape so as to make contact with pads on the testboard 19 (not shown) for receiving test signals. In the conventional rivet-connection mode, the swaging force needs to be precisely controlled in strength and direction when swaging the rivet 201. As a result, a certain gap A and a certain predetermined force can be maintained after all the golden fingers 202 have the contact with the pad on the testboard 19, thereby the impedance match can be fixed to obtain the stable test signals. During the IC device testing process, the ZIF connectors 18 must be capable of sustaining the repeatedly plugged and unplugged operations from the female plug connector 17. After a while, the golden fingers 202 will be worn out so that it will change both the gap A and the predetermined force to cause bad connections between the pad portion of the testboard 19 and the golden fingers 202, thereby the test result will be affected. Then, the testboard will have to be replaced for maintenance.

Refer to FIG. 1C. A schematic view of another conventional ZIF connector structure from U.S. Pat. No. 6,642,729 is shown. Fixed pins (i.e. rivets) 1251 and 1253 are disposed under the ZIF connectors so that the ZIF connectors can be connected to the testboard and affixed thereon.

It is to be noted that when the testboard 19 performs the IC device test, if the abnormality occurs in the gap A or the predetermined force between some golden finger of the ZIF connectors 18 and the testboard 19, the whole testboard 19 has to be removed from the test system. The ZIF connector 18 needs to be replaced and the gap A and the predetermined force need to be re-adjusted. During the steps of replacing the ZIF connector 18, a rivet head needs to be peeled off by using a sharp knife so that the rivet can be removed; however, if force is carelessly applied, the ZIF connector 18 can be easily damaged, or worse, the testboard 19 can be damaged. General speaking, the structure of the testboard 19 is very complex and it is of multiple layers. The pitch between the pads thereon is very small and needs to be reworked at a semiconductor level so that the price is extremely expensive. The cost becomes very high due to replacing the whole testboard 19, when damage is caused by adjusting or detaching a ZIF connector 18. Therefore, what is needed for industrial fields is to provide a simple and effective approach to connecting, replacing and adjusting the ZIF connectors and the testboard.

### SUMMARY OF THE INVENTION

In order to solve the above mentioned problems, the present invention provides a testboard with ZIF connectors and a method of fabricating the testboard with ZIF connectors. Particularly, the testboard is equipped with replaceable and detachably adjustable ZIF connectors. The testboard with ZIF connectors comprises a test substrate, a plurality of ZIF connectors and a plurality of detachably adjustable fastening means. The test substrate has a first surface, a second surface, and a plurality of first through-holes perpendicular to the first surface and the second surface. Each ZIF connector is arranged on the first surface of the test substrate, and each ZIF connector has a plurality of second through-holes through the ZIF connectors and pairs of electric terminals deposed on the bottom of each ZIF connector having a radial shape to contact the test substrate. Each fastening means is disposed through the first and second through-holes via the middle of each the ZIF connector for adjusting the ZIF connector's contact on the test substrate and for replacing each the ZIF connector on the test substrate with a replacement ZIF connector. Moreover, the second through-holes are arranged to one another in a spaced interval along a longitudinal direction, and the ZIF connector has a ratio of its longitudinal length L to its spaced interval I ranging from 3:1 to 5:1. Each pair of electric terminals are arranged in a spaced terminal width along a transverse direction D2 where each ZIF connector has a ratio of its transverse width Wz to its terminal width Wt ranging from 3:1 to 5:1. The longitudinal direction D1 is perpendicular to the transverse direction D2.

Therefore, the object of the present invention is to provide the testboard with the ZIF connectors, whereby it can achieve not only the purpose of replacing or repairing a damaged ZIF connector located on the testboard without replacing the whole testboard at price, but also the purpose of maintaining stable test signals in the testboard, based on the ZIF connector having such both predetermined dimensional ratios as L to I, and Wz to Wt.

Another object of the present invention is to provide the testboard with the ZIF connectors, whereby it can achieve not only the purpose of better affixing the ZIF connectors on the test substrate, but also the purpose of easily adjusting the contact force between the test substrate and the ZIF connector, based on the ZIF connector having such both predetermined dimensional ratios as L to I, and Wz to Wt.

Yet another object of the present invention is to provide the testboard with the ZIF connectors further with at least a depressor, whereby it can achieve the purpose of uniformly distributing the clamping force of the detachably adjustable fastening means applied on the ZIF connectors and the test substrate due to the depressor having such stronger structural strength resulting from its dimensional ratios like width to thickness and width to diameter.

Besides, the present invention is to provide another testboard and a method of fabricating the testboard with ZIF connectors. The testboard with ZIF connectors comprises a test substrate, at least a socket, a plurality of ZIF connectors and a plurality of detachably adjustable fastening means. The test substrate has a first surface, a second surface, and a plurality of first through-holes perpendicular to the first surface and the second surface. The socket is affixed on the second surface of the testboard for receiving an IC device under test, and is provided with a plurality of pogo pins lengthwise through the socket. Each ZIF connector is arranged on the first surface of the test substrate, and each ZIF connector has a plurality of second through-holes through the ZIF connectors and pairs of electric terminals deposed on the bottom of each ZIF connector having a radial shape to contact the test substrate. Each fastening means is disposed through the first and second through-holes via the middle of each the ZIF connector for adjusting the ZIF connector's contact on the test substrate and for replacing each the ZIF connector on the test substrate with a replacement ZIF connector. Moreover, the second through-holes are arranged to one another in a spaced interval along a longitudinal direction where each ZIF connector has a ratio of its longitudinal length L to its spaced interval I ranging from 3:1 to 5:1. Each pair of electric terminals are arranged in a spaced terminal width along a transverse direction D2 where each ZIF connector has a ratio of its transverse width Wz to its terminal width Wt ranging from 3:1 to 5:1. The longitudinal direction D1 is perpendicular to the transverse direction D2.

Therefore, the object of the present invention is to provide the testboard with the ZIF connectors, whereby it can achieve not only the purpose of replacing or repairing a damaged ZIF connector located on the testboard without replacing the whole testboard at price, but also the purpose of maintaining stable test signals in the testboard, based on the ZIF connector having such both predetermined dimensional ratios as L to I, and Wz to Wt.

Another object of the present invention is to provide the testboard with the ZIF connectors, whereby it can achieve not only the purpose of better affixing the ZIF connectors on the test substrate, but also the purpose of easily adjusting the contact force between the test substrate and the ZIF connector, based on the ZIF connector having such both predetermined dimensional ratios as L to I, and Wz to Wt.

Yet another object of the present invention is to provide the testboard with the ZIF connectors further with at least a depressor, whereby it can achieve the purpose of uniformly distributing the clamping force of the detachably adjustable fastening means applied on the ZIF connectors and the test substrate due to the depressor having such stronger structural strength resulting from its dimensional ratios like width to thickness and width to diameter.

Besides, the present invention is to provide an IC device test system and an IC device test method. The IC device test system comprises a testboard, a handler, a tester and a controller. The testboard with ZIF connectors comprises a test substrate, at least a socket, a plurality of ZIF connectors and a plurality of detachably adjustable fastening means. The test substrate has a first surface, a second surface, and a plurality of first through-holes perpendicular to the first surface and the second surface. The socket is affixed on the second surface of the testboard for receiving an IC device under test, and is provided with a plurality of pogo pins lengthwise through the socket. Each ZIF connector is arranged on the first surface of the test substrate, and each ZIF connector has a plurality of second through-holes through the ZIF connectors and pairs of electric terminals deposed on the bottom of each ZIF connector having a radial shape to contact the test substrate. Each fastening means is disposed through the first and second through-holes via the middle of each the ZIF connector for adjusting the ZIF connector's contact on the test substrate and for replacing each the ZIF connector on the test substrate with a replacement ZIF connector. Moreover, the second through-holes are arranged to one another in a spaced interval along a longitudinal direction where each ZIF connector has a ratio of its longitudinal length L to its spaced interval I ranging from 3:1 to 5:1. Each pair of electric terminals are arranged in a spaced terminal width along a transverse direction D2 where each ZIF connector has a ratio of its transverse width Wz to its terminal width Wt ranging from 3:1 to 5:1. The longitudinal direction D1 is perpendicular to the transverse direction D2. The handler is provided for receiving the IC devices under test and placing the IC devices under test on the testboard, and classifying in accordance with testing result after test of the IC devices. The tester is provided with female plugs for connecting the plurality of corresponding ZIF connectors during test signal transmission. The controller is provided for sending, receiving and processing the test signal from the tester.

Therefore, the object of the present invention is to provide the IC device test system having a testboard with the ZIF connectors, whereby it can achieve not only the purpose of replacing or repairing a damaged ZIF connector located on the testboard without replacing the whole testboard at price, but also the purpose of maintaining stable test signals in the testboard, based on the ZIF connector having such both predetermined dimensional ratios as L to I, and Wz to Wt.

Another object of the present invention is to provide the IC device test system having a testboard with the ZIF connectors, whereby it can achieve not only the purpose of better affixing the ZIF connectors on the test substrate, but also the purpose of easily adjusting the contact force between the test substrate and the ZIF connector, based on the ZIF connector having such both predetermined dimensional ratios as L to I, and Wz to Wt.

Yet another object of the present invention is to provide the IC device test system having a testboard with the ZIF connectors further with at least a depressor, whereby it can achieve the purpose of uniformly distributing the clamping force of the detachably adjustable fastening means applied on the ZIF connectors and the test substrate due to the depressor having such stronger structural strength resulting from its dimensional ratios like width to thickness and width to diameter.

### BRIEF DESCRIPTION OF THE DRAWINGS

FIG. 1A is a schematic view of a conventional IC device test system;

FIG. 1B is a cross-sectional view of a conventional connection mode for a ZIF connector and a testboard;

FIG. 1C is a three-dimensional view of a conventional ZIF connector and a fixed pin;

FIG. 2 is a 3D view of a testboard equipped with ZIF connectors in accordance with a first embodiment of the present invention;

FIG. 3 is an A-A sectional view of the testboard equipped with the ZIF connector in FIG. 2;

FIG. 4 is a front view of the testboard equipped with the ZIF connector in FIG. 2;

FIG. 5 is a bottom view of the testboard equipped with a first depressor in FIG. 2;

FIG. 6 is a schematic view of another testboard equipped with the ZIF connector in accordance with a second embodiment of the present invention; and

FIG. 7 is a schematic view of an IC device test system in accordance with a fifth embodiment of the present invention.

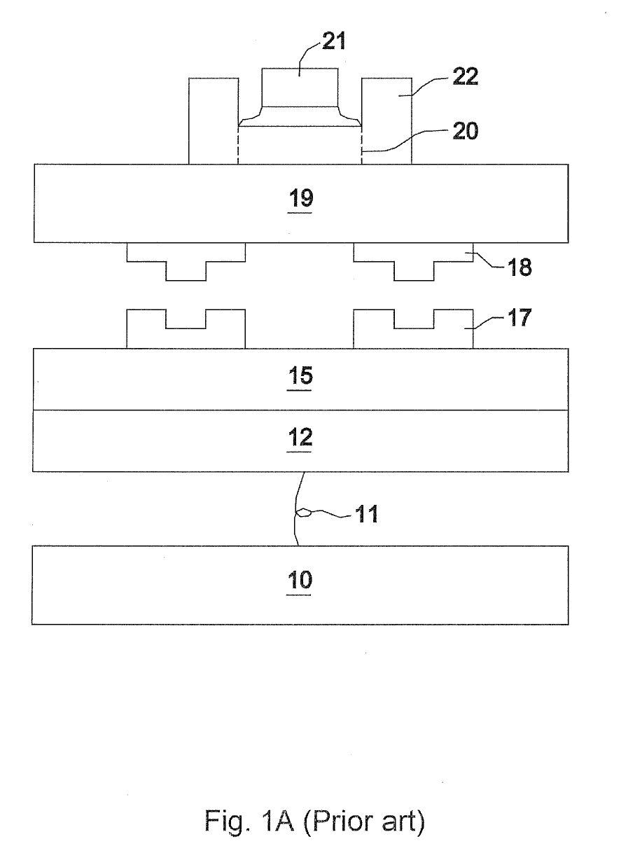

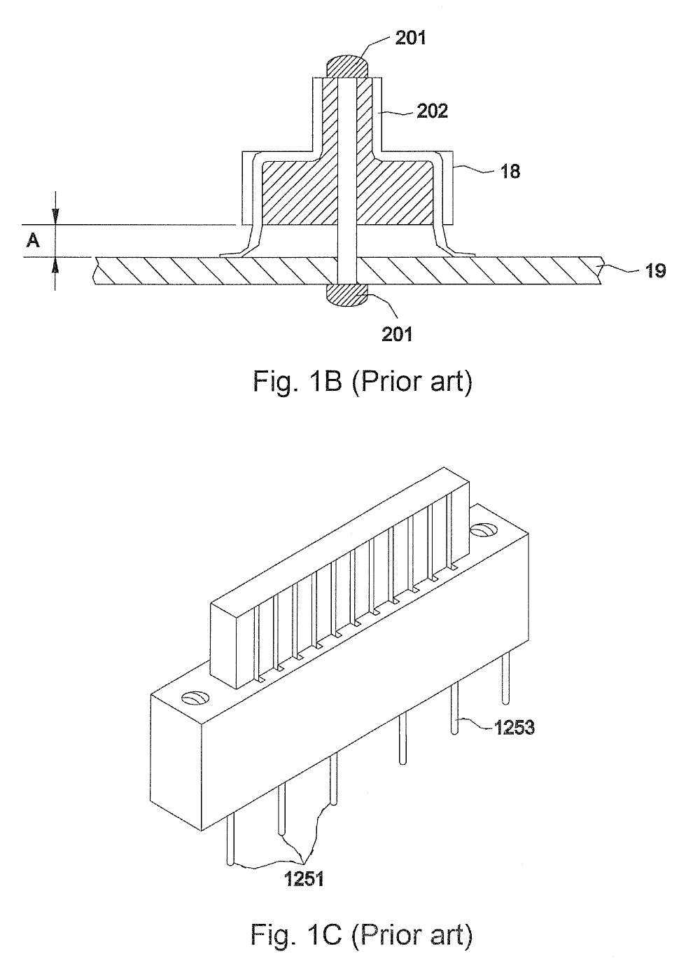

### DETAILED DESCRIPTION OF THE PREFERRED EMBODIMENTS

Since the present invention discloses a final test for an IC device in the semiconductor back-end processing, wherein the basic principles of the semiconductor manufacturing are well-known by those skilled in the art, the following description will omit the description of the principles. Moreover, the diagrams included in the following are not completely drawn according to the real size and are only used to demonstrate features related to the present invention.

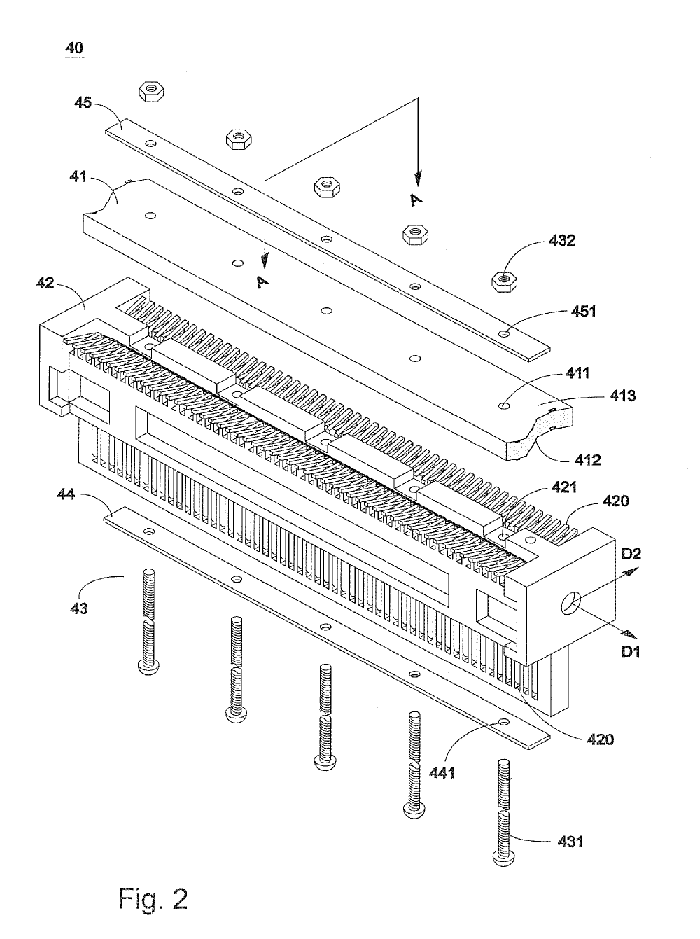

Refer to FIG. 2, a testboard with ZIF connectors is shown in accordance with the first preferable embodiment of the present invention. The testboard 40 comprises a test substrate 41, a plurality of ZIF connectors 42 and a plurality of detachably adjustable fastening means 43. The test substrate 41 has a first surface 412, a second surface 413, and a plurality of first through-holes 411 perpendicular to the first surface 412 and the second surface 413 of the test substrate 41. Pairs of first electric contacts (not shown), arranged on the first surface 412 and adjacent to both sides of first through-holes 411, are adapted to connect a plurality of second electric contacts (not shown) arranged on the second surface 413 of the test substrate 41.

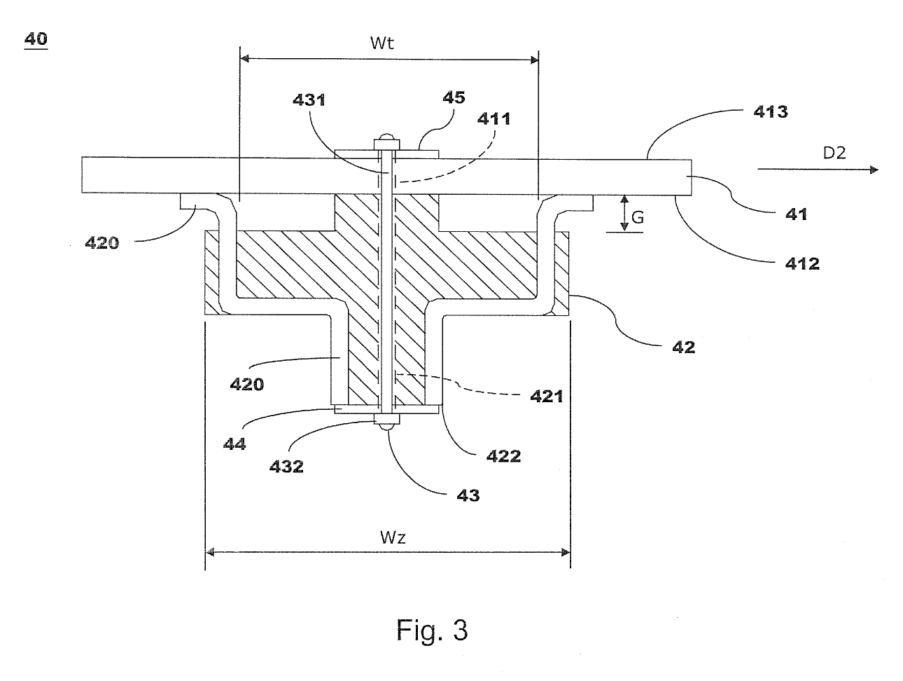

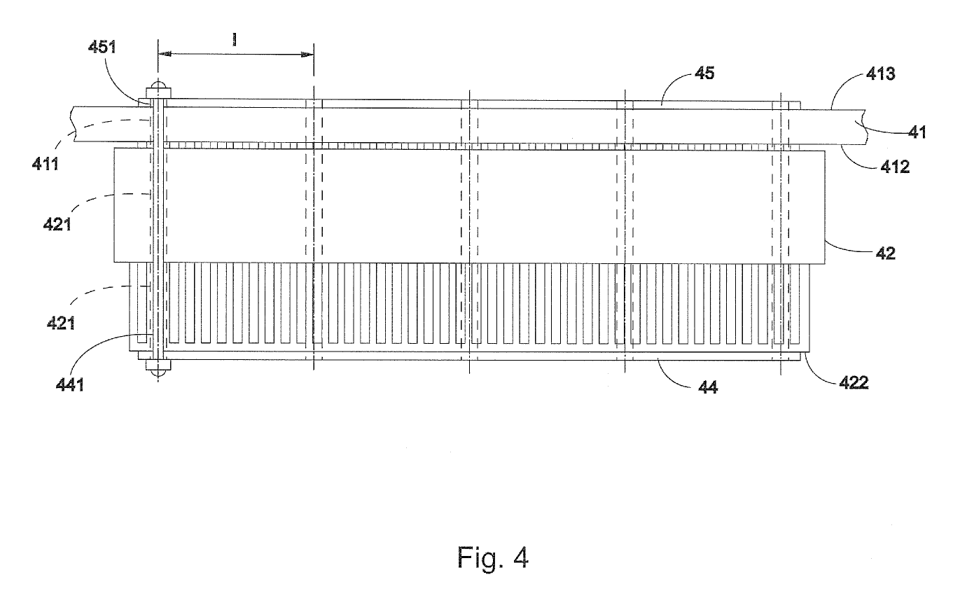

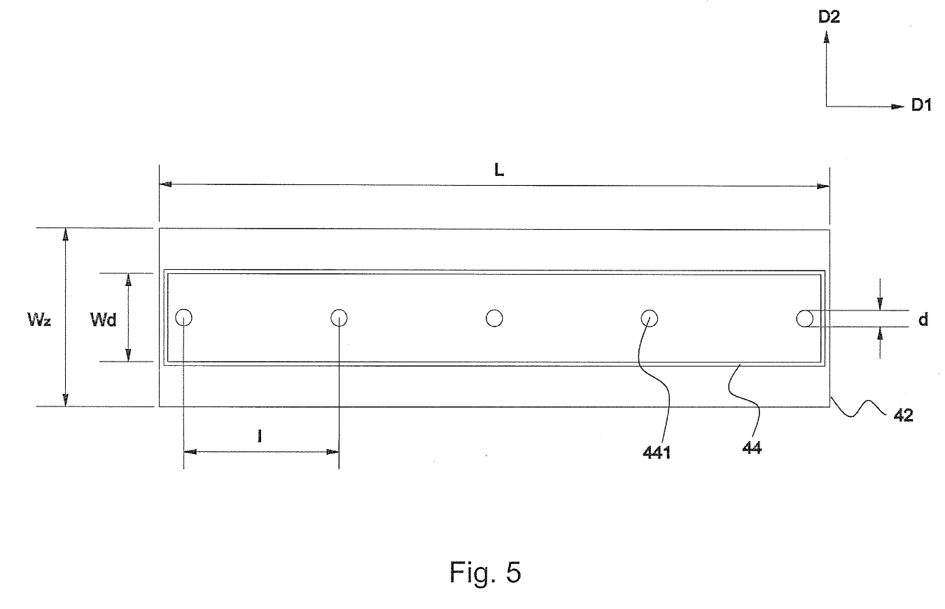

Refer to FIGS. 2-5, each of the ZIF connector 42 has a plurality of pairs of electric terminals 420, disposed from its top portion to its bottom portion of each ZIF connector 42 and arranged in a terminal width Wt exposed on its bottom portion. Each ZIF connector 42 has a plurality of parallelly arranged second through-holes 421 through the middle of the ZIF connector 42. Particularly, the second through-holes 421 are arranged to one another in a spaced interval I (shown in FIG. 4) along a longitudinal direction D1 where each ZIF connector has a ratio of its longitudinal length L (shown in FIG. 5) to its spaced interval I ranging from 3:1 to 5:1. Since each pair of electric terminals 420 are arranged in the spaced terminal width Wt (shown in FIG. 3) along a transverse direction D2 on the bottom portion of the ZIF connector 42, and thus a ratio of the ZIF connector's transverse width Wz (shown in FIG. 5) to the terminal width Wt has a value ranging from 3:1 to 5:1, wherein the longitudinal direction D1 is perpendicular to the transverse direction D2. Besides, there is a gap G (shown in FIG. 3) between the test substrate 41 and the ZIF connector 42. Therefore, according to the above dimensional ratios, the plurality of detachably adjustable fastening means 43 passed through the first through-holes 411 and second through-holes 421 can achieve not only the purpose of better affixing the ZIF connectors 42 on the first surface 411 of the test substrate 41, but also the purpose of easily adjusting the contact force through the gap G between the test substrate 41 and the ZIF connector 42. Besides, communication of test signal during IC test between the plurality of ZIF connectors 42 and the test substrate are fulfilled by means of contacting the pairs of electric terminals 420 of each ZIF connectors 42 with the pairs of first electric contacts of the test substrate 41. Besides, if some pairs of electric terminals of a ZIF connector have bad contacts with the test substrate, the technician just either adjusts some adjustable fastening means corresponding to the “bad contact” pairs of electric terminals or replaces bad ZIF connector(s) for obtaining better contact force between the electric terminals of the ZIF connector and the test substrate, without replacing the whole test substrate at price.

Referred back to FIGS. 2-5, in the above-mentioned first preferable embodiment, at least a first depressor 44 may be further provided on a top surface 422 of the top portion of the ZIF connectors 42, and at least a second depressor 45 may also be further provided on a second surface 413 of the test substrate 41 as well. Each of the first and second depressors 44, 45 has a predetermined width and thickness so that it has a width to thickness ratio ranging from 3:1 to 4:1. Besides, each of the first and second depressor 44, 45 is respectively provided with a plurality of third and fourth through-holes 441, 451 of predetermined diameters located on the opposite side of the second and first through-holes 421, 411, respectively, and thus the depressor can help the fastening means 43 clamp both ZIF connector and test substrate securely. On the other hand, the first depressor 44 and second depressor 45 may be provided separately or together. For example, referred to FIG. 5, the first depressor 44 with a width Wd has a plurality of third through-holes 441 with a diameter d, and is disposed on the top surface 422 of the top portion of the ZIF connectors 42 with a width Wz, where the first depressor 44 has a ratio of its width Wd to the diameter d of each third through-hole 44 ranging from 2:1 to 3:2. Similarly, the second depressor 45 has a width Wd′ to diameter d′ ratio similar to that of the first depressor's 44, where the width Wd′ (not shown) is for the second depressor 4, and the diameter d′ (not shown) is for the fourth through-hole 451. Therefore, each of the first and second depressor 44, 45 has stronger structural strength due to its dimensional ratios (i.e width to thickness ratio and width to diameter ratio) so as to uniformly distribute the clamping force of the detachably adjustable fastening means 43 applied on the ZIF connectors 42 and the test substrate 41, respectively.

Referred back to FIG. 2, the fastening means 43 are detachably adjustable and can be a combination of a bolt 431 and a nut 432, or a combination of a bolt 431 and a fastening plate (not shown) having a plurality of through-holes (not shown) corresponding to the third or fourth through-holes 441, 451. When assembled, a bolt 431 may pass through the ZIF connector 42 and the test substrate 41 from the downside of the ZIF connector 42 to affix the nut 432 on the upside of the test substrate 41. Alternatively, the bolt 431 may pass through the test substrate 41 and the ZIF connectors 42 from the topside of the test substrate 41 to affix the nut 432 on the downside of the ZIF connectors 42. Besides, the plurality of the ZIF connectors 42 are arranged in an array shape. The number of the bolt 431 is not limited as long as the force to clamp the ZIF connector 42 to the test substrate 41 is strong enough to make a stable connection therein. The fastening plate is provided with multiple holes like multiple nuts to engage with multiple bolts 431. In order to enhance the fastening force to affix the ZIF connector 42 to the test substrate 41, the sealing gel or resin may be further provided in the cross locking portions of the fastening means 43 to decrease the loosening possibility of the fastening means 43 for connecting the ZIF connector 42 with the test substrate 41.

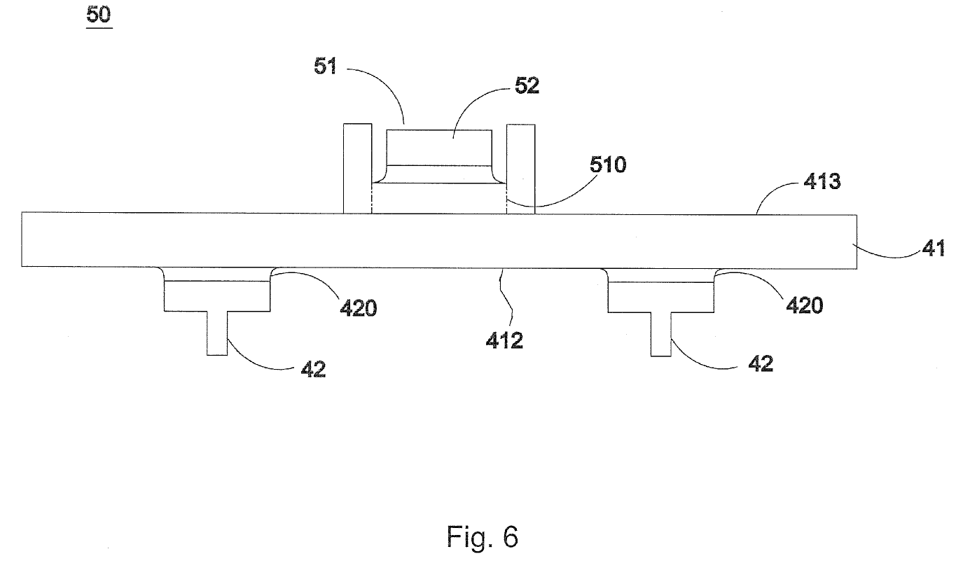

Refer to FIG. 6. Another testboard with ZIF connectors for IC test is shown in accordance with a second preferable embodiment of the present invention. The testboard 50 includes at least a test substrate 41, a plurality of ZIF connectors 42 each of which has a plurality of pairs of electric terminals 420 to contact the pairs of first electric contacts (not shown) of the test substrate 41 to communicate test signal during IC test, at least a socket 51 and a plurality of detachably adjustable fastening means (not shown) that are equivalent to the fastening means 43 of the first preferable embodiment. The socket 51 is affixed on the second surface 413 of the testboard 41 for receiving an integrated circuit device under test 52, and the socket 51 is provided with a plurality of pogo pins 510 lengthwise through the socket 51. The technical features, dimensional ratios and relating structures of the testboard 40 including the test substrate 41, ZIF connectors 42 and the detachably adjustable fastening means are the same as described in the first embodiment.

An assembling method, for the testboard with the ZIF connectors based on the first preferable embodiment, is shown in accordance with a third preferable embodiment of the present invention. The assembling method includes the following steps:

(1) provide a test substrate 41 having a first surface 412, a second surface 413, and a plurality of first through-holes 411 perpendicular to the first surface 412 and the second surface 413 of the test substrate 41, where pairs of first electric contacts (not shown), are arranged on the first surface 412 and adjacent to both sides of first through-holes 411, and are adapted to connect a plurality of second electric contacts (not shown) arranged on the second surface 413 of the test substrate 41;

(2) provide a plurality of ZIF connectors 42 where the ZIF connectors 42 are arranged on the first surface 411 of the test substrate 41, and each of the plurality of ZIF connectors 42 has a plurality of parallel second through-holes 412 from the top to the bottom of the ZIF connectors 42 and pairs of electric terminals 420 are deposed on the bottom of each ZIF connector 42 for contacting the first electric contacts (not shown) of the test substrate 41; and

(3) provide a plurality of detachable and detachably adjustable fastening means 43, passing through the first through-holes 413 and the second through-holes 421 so as to affix the ZIF connectors 42 on the first surface 411 of the test substrate 41.

In the assembling method of the above mentioned embodiment, the technical features, dimensional ratios and relating structures of the testboard 40 including the test substrate 41, ZIF connectors 42 and the detachably adjustable fastening means 43 are the same as described in the first embodiment.

A method, fabricating a testboard with ZIF connectors based on the second preferable embodiment, is shown in accordance with a fourth preferable embodiment of the present invention, comprising the steps of:
(1) providing a test substrate 41, where the test substrate 41 has a first surface 412, a second surface 413, and a plurality of first through-holes 411 through the first surface 412 and the second surface 413. Pairs of the first electric contacts (not shown) are disposed on both sides of the first through-holes 411 of the first surface 412;
(2) providing at least a socket 51, where the socket 51 is affixed on the second surface 412 of the testboard 41 for receiving an integrated circuit device under test 52, and a plurality of pogo pins 510 are provided lengthwisely through the socket 51;
(3) providing a plurality of ZIF connectors 42, where the plurality of ZIF connectors are arranged on the first surface 412 of the test substrate 41, and each of the plurality of ZIF connectors 42 has a plurality of second through-holes 421 parallelly arranged through the ZIF connectors, and pairs of electric terminals 420 are deposed on the bottom of each ZIF connector 42 for contacting the first electric contacts (not shown) of the test substrate 41; and
(4) providing a plurality of detachably adjustable fastening means, which are equivalent to the fastening means 43 of the first preferable embodiment.

In the assembling method of the above mentioned embodiment, the technical features, dimensional ratios and relating structures of the above elements such as the test substrate 41, the socket 51, the ZIF connector 42 and the detachably adjustable fastening means are the same as described in the second embodiment.

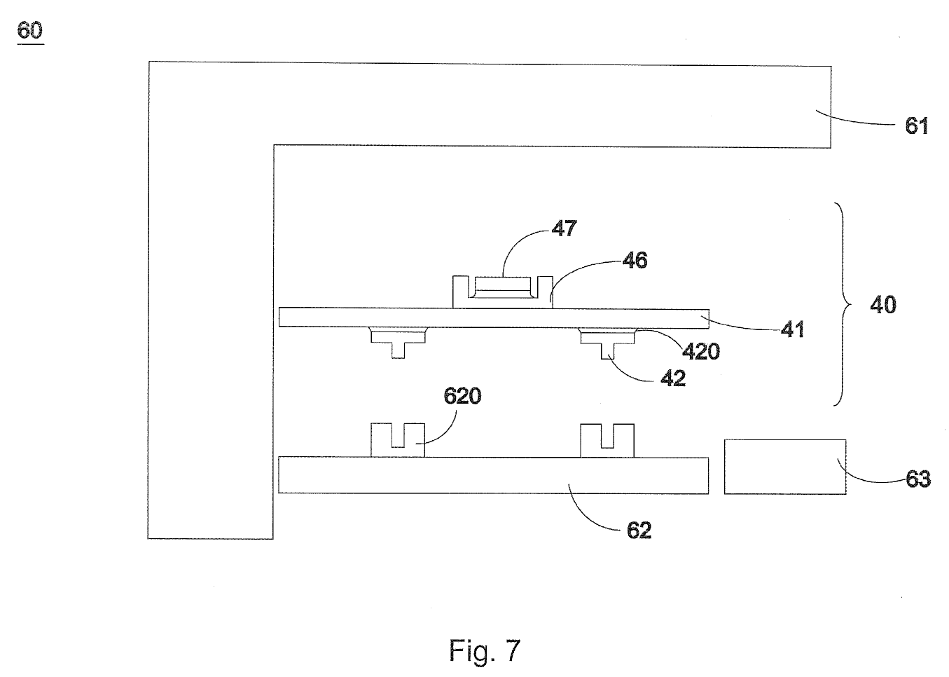

Refer to FIG. 7, an IC device test system is shown in accordance with a fifth preferable embodiment of the present invention. The IC device test system 60 comprises a testboard 40, a handler 61, a tester 62 and a controller 63. The testboard 40 comprises a test substrate 41, at least a socket 51, a plurality of ZIF connectors 42 each of which has a plurality of pairs of electric terminals 420 to contact the pairs of first electric contacts (not shown) of the test substrate 41 to communicate test signal during IC test, at least a socket 51 and a plurality of detachably adjustable fastening means (not shown), and a plurality of detachably adjustable fastening means (not shown) that are equivalent to the fastening means 43 of the first preferable embodiment. The handler 61 includes a plurality of trays such that IC devices under test 52 are loaded onto the trays ready for test in the testboard 40. A tester 62 is provided with female plugs 620 to connect the plurality of corresponding ZIF connectors 42 for handling the test signals. A controller 63 is provided for sending calculated test results back to the handler 61 after analyzing and processing the test signals from the tester 62. The handler 61 further classifies the tested IC devices in accordance with the testing results. The technical features, dimensional ratios and relating structures of the testboard 40 are the same as described in the second embodiment.

An IC device test method, fabricating an IC device test system based on the fifth preferable embodiment, is illustrated in accordance with a sixth preferable embodiment of the present invention. The IC device test method includes the following steps:

(1) providing an integrated circuit device under test 52;

(2) providing a testboard 40 to perform an IC final test of the integrated circuit device under test 52, where the testboard 40 comprises a test substrate 41, at least a socket 51, a plurality of ZIF connectors 42 each of which has a plurality of pairs of electric terminals 420 to contact the pairs of first electric contacts (not shown) of the test substrate 41 to communicate test signal during IC test, at least a socket 51 and a plurality of detachably adjustable fastening means (not shown), and a plurality of detachably adjustable fastening means (not shown) that are equivalent to the fastening means 43 of the first preferable embodiment;

(3) providing a handler 61, where the handler 61 comprises a plurality of trays such that IC devices under test 52 are loaded onto the trays ready for test in the testboard 40, and further classifies the tested IC devices 52 in accordance with a testing results as well;

(4) providing a tester 62, where the tester 63 is provided with female plugs 620 to connect the plurality of corresponding ZIF connectors 42 for handling the test signals; and

(5) providing a controller 63, where the controller 63 is provided for sending calculated test results back to the handler 61 after analyzing and processing the test signals from the tester 62.

The above mentioned preferred embodiments of the present invention are not meant to limit the scope of the present invention. The description of the present invention should be understood by those skilled in the art. Moreover, any changes or modifications or the equivalent thereof that can be made without departing from spirit of the present invention should be protected by the following claims.

What is claimed is:

1. A testboard with ZIF connectors, comprising:
a test substrate having a first surface, a second surface, a plurality of first through-holes, the plurality of first through-holes being perpendicular to the first surface and the second surface of said test substrate;
a plurality of ZIF connectors being arranged on said first surface of said test substrate, each of said plurality of ZIF connectors having a plurality of second through-holes parallelly arranged through said ZIF connectors, and pairs of electric terminals being deposed on the bottom of each ZIF connector and said electric terminals having a radial shape for contacting said test substrate; and
a plurality of detachably adjustable fastening means being disposed through said first through-holes and said second through-holes through the middle of each said ZIF connector for adjusting said ZIF connectors on said test substrate in better contact and for replacing each said ZIF connector on said test substrate with a replacement ZIF connector;
wherein said second through-holes are arranged to one another in a spaced interval along a longitudinal direction (D1), and each said ZIF connector has a ratio of longitudinal length (L) to said spaced interval (I) ranging from 3:1 to 5:1,
wherein each said pair of electric terminals are arranged in a spaced terminal width (Wt) along a transverse direction (D2), and each said ZIF connector has a ratio of transverse width (Wz) to said terminal width (Wt) ranging from 3:1 to 5:1, and
wherein said longitudinal direction (D1) is perpendicular to said transverse direction (D2).

2. The testboard of claim 1, further comprising a plurality of first depressors on a top surface of said ZIF connectors, wherein a plurality of third through-holes are provided on an opposite side of said second through-holes so that the detachably adjustable fastening means may pass therethrough for being affixed thereon.

3. The testboard of claim 1, further comprising a plurality of second depressors on a second surface of said test substrate, wherein a plurality of fourth through-holes are provided on an opposite side of said first through-holes so that said detachably adjustable fastening means may pass therethrough for being affixed thereon.

4. The testboard of claim 1, further comprising a plurality of first and second depressors respectively on said top surface of said ZIF connectors and on a second surface of said test substrate, wherein a plurality of third and fourth through-holes are respectively provided on an opposite side of said second and first through-holes so that said detachably adjustable fastening means may pass therethrough for being affixed thereon.

5. The testboard of claim 2, wherein each of said first depressors has a width to thickness ratio ranging from 3:1 to 4:1.

6. The testboard of claim 3, wherein each of said second depressors has a width to thickness ratio ranging from 3:1 to 4:1.

7. The testboard of claim 5, wherein each of said first depressors has a predetermined width and each of said third through-holes has a predetermined diameter, so as to have a width to diameter ratio ranging from 2:1 to 3:2.

8. The testboard of claim 6, wherein each of said second depressors has a predetermined width and each of said fourth through-holes has a predetermined diameter, so as to have a width to diameter ratio ranging from 2:1 to 3:2.

9. The testboard of claim 1, wherein said plurality of detachably adjustable fastening means comprise a combination of bolts and nuts.

10. The testboard of claim 1, wherein said plurality of detachably adjustable fastening means comprise bolts and fasten plates with multiple holes for fastening said bolts thereon.

11. The testboard of claim 1, wherein said plurality of detachably adjustable fastening means are fastened adjacent on said second surface of said test substrate.

12. The testboard of claim 1, wherein said plurality of detachably adjustable fastening means are fastened adjacent on said bottom side of the ZIF connectors.

13. The testboard of claim 1, wherein a sealing gel or resin is further provided in a portion on which said detachably adjustable fastening means are fastened.

14. The testboard of claim 1, wherein said plurality of ZIF connectors are arranged in an array shape.

15. A testboard with ZIF connectors, comprising:
a test substrate having a first surface, a second surface, a plurality of first through-holes, said plurality of first through-holes being perpendicular to said first surface and said second surface of said test substrate;
at least a socket being affixed on said second surface of said testboard for receiving an IC device under test, said socket being provided with a plurality of pogo pins lengthwise through said socket;
a plurality of ZIF connectors being arranged on said first surface of said test substrate, each of said plurality of ZIF connectors having a plurality of second through-holes parallelly arranged through said ZIF connectors, and pairs of electric terminals being deposed on the bottom of each ZIF connector and said electric terminals having a radial shape for contacting said test substrate; and
a plurality of detachably adjustable fastening means being disposed through said first through-holes and said second through-holes through the middle of each said ZIF connector for adjusting said ZIF connectors on said test substrate in better contact and for replacing each said ZIF connector on said test substrate with a replacement ZIF connector;
wherein said second through-holes are arranged to one another in a spaced interval along a longitudinal direction (D1), and each said ZIF connector has a ratio of longitudinal length (L) to said spaced interval (I) ranging from 3:1 to 5:1,
wherein each said pair of electric terminals are arranged in a spaced terminal width (Wt) along a transverse direction (D2), and each said ZIF connector has a ratio of transverse width (Wz) to said terminal width (Wt) ranging from 3:1 to 5:1, and
wherein said longitudinal direction (D1) is perpendicular to said transverse direction (D2).

16. An IC device test system, comprising:
a testboard comprising:
a test substrate having a first surface, a second surface, a plurality of first through-holes, said plurality of first through-holes being perpendicular to said first surface and said second surface of said test substrate;
at least a socket being affixed on said second surface of said test substrate for receiving at least an IC device under test, said socket being provided with a plurality of pogo pins lengthwise through said socket;
a plurality of ZIF connectors being arranged on said first surface of said test substrate, each of said plurality of ZIF connectors having a plurality of second through-holes parallelly arranged through said ZIF connectors, and pairs of electric terminals being deposed on the bottom of each said ZIF connector and said electric terminals having a radial shape for contacting said test substrate; and
a plurality of detachably adjustable fastening means being disposed through the first through-holes and the second through-holes for adjusting said ZIF connectors on said test substrate in better contact and for replacing each said ZIF connector on said test substrate with a replacement ZIF connector;
a handler for receiving said IC devices under test and placing said IC devices under test on said testboard, and classifying in accordance with testing result of said IC devices after test;
a tester with female plugs for connecting said plurality of corresponding ZIF connectors; and
a controller for sending, receiving and processing a test signal of said tester;
wherein said second through-holes are arranged to one another in a spaced interval along a longitudinal direction (D1), and each said ZIF connector has a ratio of longitudinal length (L) to said spaced interval (I) ranging from 3:1 to 5:1,
wherein each said pair of electric terminals are arranged in a spaced terminal width (Wt) along a transverse direction (D2), and each said ZIF connector has a ratio of transverse width (Wz) to said terminal width (Wt) ranging from 3:1 to 5:1, and
wherein said longitudinal direction (D1) is perpendicular to said transverse direction (D2).
